(19) United States
(12) Patent Application Publication
(10) Pub. No.: US 2026/0215348 A1
(43) Pub. Date: Jul. 23, 2026

(54) SEMICONDUCTOR PACKAGE INCLUDING SPACER

(71) Applicant: SAMSUNG ELECTRONICS CO., LTD., Suwon-si (KR)

(72) Inventors: Sojeong HONG, Suwon-si (KR); Taesung KIM, Suwon-si (KR); Keehoon KIM, Suwon-si (KR)

(73) Assignee: SAMSUNG ELECTRONICS CO., LTD., Suwon-si (KR)

(21) Appl. No.: 19/408,896

(22) Filed: Dec. 4, 2025

(30) Foreign Application Priority Data
Jan. 23, 2025 (KR) 10-2025-0010559

(51) Int. Cl. H10W 90/00; H10W 70/68; H10W 72/00; H10W 90/24

(52) U.S. Cl. CPC H10W 90/754; H10W 70/68; H10W 72/884; H10W 90/24; H10W 90/732

(57) ABSTRACT

A semiconductor package includes a substrate having an upper surface on which a plurality of bonding fingers and a connection finger are disposed; a chip structure disposed on the substrate and including a plurality of semiconductor chips including pads disposed on upper surfaces thereof, respectively, wherein the plurality of semiconductor chips are offset and stacked in the first direction; a bonding wire structure electrically connecting the pads to a bonding finger closest to the pad among the plurality of bonding fingers; a semiconductor die disposed on the chip structure and including a connection pad disposed on an upper portion, wherein the semiconductor die has an overhang in the first direction; an insulating structure disposed between the bonding fingers and the connection finger, and formed between the semiconductor die and the substrate; and a connection wire structure electrically connecting the connection pad of the semiconductor die to the connection finger.

### CROSS-REFERENCE TO RELATED APPLICATION(S)

This application claims benefit of priority to Korean Patent Application No. 10-2025-0010559 filed on Jan. 23, 2025 in the Korean Intellectual Property Office, the disclosure of which is incorporated herein by reference in its entirety.

### BACKGROUND

Example embodiments of the present disclosure relate to a semiconductor package and a method of manufacturing the same.

Recently, high performance, high capacity, and high reliability of a semiconductor package mounted on an electronic device have been required. Accordingly, development of a semiconductor package including a plurality of semiconductor chips embedded therein has been conducted.

### SUMMARY

An example embodiment of the present disclosure is to provide a semiconductor package having improved reliability and a method of manufacturing the same.

According to an example embodiment of the present disclosure, a substrate having an upper surface on which a first bonding finger, a second bonding finger, and a third bonding finger are disposed; a first semiconductor chip disposed on the substrate, and including a first pad disposed on an upper portion of the first semiconductor chip and a first adhesive layer disposed on a lower portion of the first semiconductor chip; a first bonding wire structure electrically connecting the first pad of the first semiconductor chip to the first bonding finger; a second semiconductor chip disposed on the first semiconductor chip, and including a second pad disposed on an upper portion of the second semiconductor chip and a second adhesive layer disposed on a lower portion of the second semiconductor chip, the second adhesive layer covering an upper portion of the first bonding wire structure, and the second semiconductor chip having a first overhang in a first direction; a second bonding wire structure electrically connecting the second pad of the second semiconductor chip to the second bonding finger; a third semiconductor chip disposed on the second semiconductor chip, and including a third pad disposed on an upper portion of the third semiconductor chip, and a third adhesive layer disposed on a lower portion of the third semiconductor chip, the third adhesive layer covering an upper portion of the second bonding wire structure, and the third semiconductor chip having a second overhang in the first direction; a third bonding wire structure electrically connecting the third pad of the third semiconductor chip to the third bonding finger; and a support structure disposed between the second bonding finger and the third bonding finger and formed between the third semiconductor chip and the substrate.

According to an example embodiment of the present disclosure, a substrate having a first side and a second side opposing each other in a first direction, and an upper surface on which 1-1, 1-2, and 1-3 bonding fingers arranged in order toward the first side are disposed; a 1-1 semiconductor chip disposed on the substrate and including a 1-1 pad disposed on an upper portion of the 1-1 semiconductor chip; a 1-1 bonding wire structure electrically connecting the 1-1 pad of the 1-1 semiconductor chip to the 1-1 bonding finger and extending toward the first side; a 1-2 semiconductor chip disposed on the 1-1 semiconductor chip and including a 1-2 pad disposed on an upper portion of the 1-2 semiconductor chip; a 1-2 bonding wire structure electrically connecting the 1-2 pad of the 1-2 semiconductor chip to the 1-2 bonding finger and extending toward the first side; a 1-3 semiconductor chip disposed on the 1-2 semiconductor chip and including a 1-3 pad disposed on an upper portion of the 1-3 semiconductor chip, the 1-3 semiconductor chip having a first overhang region; a 1-3 bonding wire structure electrically connecting the 1-3 pad of the 1-3 semiconductor chip to the 1-3 bonding finger and extending toward the first side; and a first support structure disposed between the 1-3 semiconductor chip and the substrate in the first overhang region, wherein the first support structure is disposed between the 1-2 and 1-3 bonding fingers, and wherein a minimum distance between the first support structure and the 1-2 bonding finger is smaller than a minimum distance between the first support structure and the 1-3 bonding finger.

According to an example embodiment of the present disclosure, a substrate having an upper surface on which a plurality of bonding fingers and a connection finger are disposed; a chip structure disposed on the substrate and including a plurality of semiconductor chips including pads disposed on upper surfaces thereof, respectively, wherein the plurality of semiconductor chips are offset and stacked in a first direction; a bonding wire structure electrically connecting the pads of the plurality of semiconductor chips to a bonding finger closest to the pad among the plurality of bonding fingers; a semiconductor die disposed on the chip structure and including a connection pad disposed on an upper portion, wherein the semiconductor die has an overhang in the first direction; an insulating structure disposed between the plurality of bonding fingers and the connection finger, and formed between the semiconductor die and the substrate; and a connection wire structure electrically connecting the connection pad of the semiconductor die to the connection finger.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor package according to an example embodiment of the present disclosure;

FIG. 2 is a cross-sectional diagram taken along line I-I′ in FIG. 1;

FIG. 3 is a plan diagram illustrating a semiconductor package according to an example embodiment of the present disclosure;

FIG. 4 is a cross-sectional diagram taken along line I-I′ in FIG. 3;

FIG. 5A, FIG. 5B, FIG. 5C, FIG. 5D and FIG. 5E are cross-sectional diagrams illustrating a process of manufacturing a semiconductor package according to an example embodiment of the present disclosure; and

FIG. 6A, FIG. 6B, FIG. 6C, FIG. 6D, FIG. 6E and FIG. 6F are cross-sectional diagrams illustrating a process of manufacturing a semiconductor package according to an example embodiment of the present disclosure.

### DETAILED DESCRIPTION

Hereinafter, embodiments of the present disclosure will be described as follows with reference to the accompanying drawings.

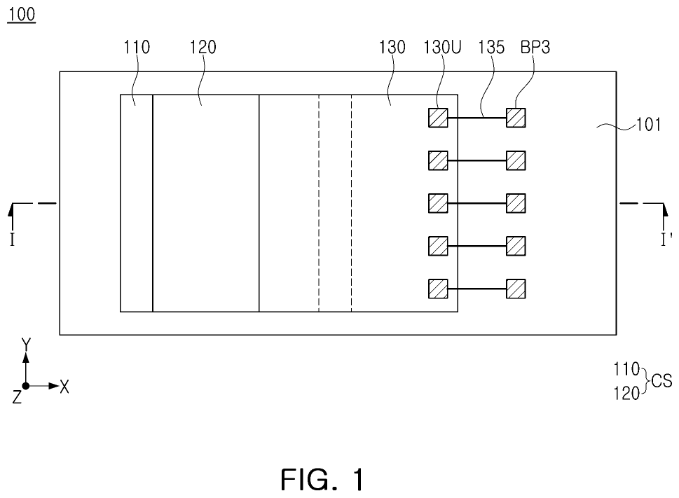

FIG. 1 is a plan diagram illustrating a semiconductor package according to an example embodiment.

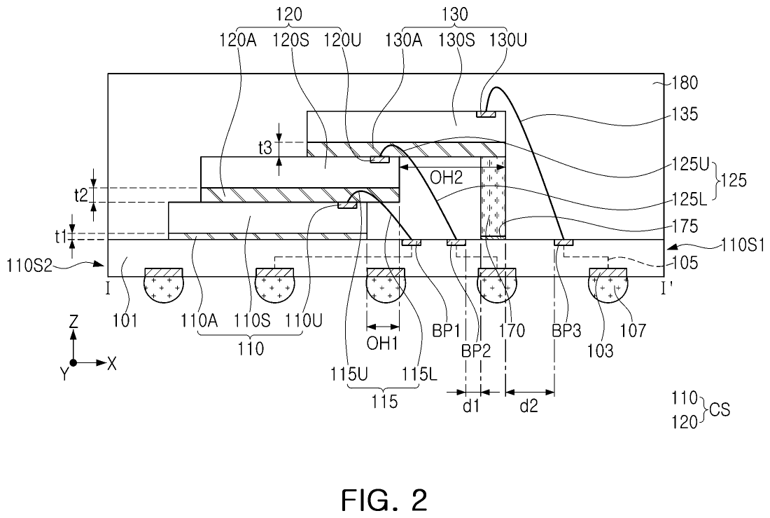

FIG. 2 is a cross-sectional diagram taken along line I-I′ in FIG. 1.

Referring to FIGS. 1 and 2, a semiconductor package 100 in an example embodiment may include a substrate 101, a plurality of semiconductor chips (e.g., 110, 120, and 130), and a plurality of bonding wire structures (e.g., 115, 125, and 135). Also, the semiconductor package 100 may further include a support structure 170 and an adhesive film 175. Also, the semiconductor package 100 may further include an encapsulant 180.

The plurality of semiconductor chips may include first to third semiconductor chips 110, 120, and 130 stacked in order on the substrate 101.

A first semiconductor chip 110 may include a first chip body 110S, a second semiconductor chip 120 may include a second chip body 120S, and a third semiconductor chip 130 may include a third chip body 130S. The first, second, and third chip bodies 110S, 120S, and 130S may have the same size. For example, the first, second, and third chip bodies 110S, 120S, and 130S may have substantially the same length in the first direction (e.g., X-direction) and may have substantially the same width in the second direction (e.g., Y-direction).

The first semiconductor chip 110 may further include a first pad 110U disposed on an upper portion of the first chip body 110S, the second semiconductor chip 120 may further include a second pad 120U disposed on an upper portion of the second chip body 120S, and the third semiconductor chip 130 may further include a third pad 130U disposed on an upper portion of the third chip body 130S.

In an example embodiment, the first and second semiconductor chips 110, 120 may be collectively referred to as a chip structure CS.

The substrate 101 may be configured as a substrate for a semiconductor package including a printed circuit board (PCB), a ceramic substrate, a glass substrate, a tape interconnection substrate, or the like. For example, the substrate 101 may be a double-sided printed circuit board (double-sided PCB) or a multilayer printed circuit board (multilayer PCB).

The substrate 101 may have a first side 110S1 and a second side 110S2 opposing each other in the first direction (e.g., X-direction), and may include first bonding fingers BP1, second bonding fingers BP2, and third bonding fingers BP3 disposed on an upper surface, a bump pad 103 disposed on a lower surface of the substrate 101, and an interconnection circuit 105 electrically connecting the components. The first bonding fingers BP1, the second bonding fingers BP2, the third bonding fingers BP3, and the bump pads 103 may include at least one metal selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals. Connection bumps 107 may be disposed on a lower portion of the bump pads 103. The connection bumps 107 may include, for example, tin (Sn) or an alloy including tin (Sn) (e.g., Sn—Ag—Cu). The connection bumps 107 may be electrically connected to an external device such as a module substrate, a system board, or the like.

The first bonding fingers BP1, the second bonding fingers BP2, and the third bonding fingers BP3 may be disposed in order on an upper surface of the substrate 101 in the first direction (e.g., X-direction). For example, the first bonding fingers BP1, the second bonding fingers BP2, and the third bonding fingers BP3 may be arranged in order from the second side 110S2 of the substrate 101 to the first side 110S1.

Each of the first bonding fingers BP1, the second bonding fingers BP2, and the third bonding fingers BP3 may be arranged on an upper surface of the substrate 101 in the second direction (e.g., Y-direction).

The first bonding fingers BP1 may be electrically connected to the first pad 110U of the first semiconductor chip 110 through the first bonding wire structure 115. The first bonding fingers BP1 may be electrically connected to bump pad 103 through interconnection circuit 105. The first bonding fingers BP1 may include a signal pad, a power pad, and a ground pad.

The second bonding fingers BP2 may be electrically connected to the second pad 120U of the second semiconductor chip 120 through the second bonding wire structure 125. The second bonding fingers BP2 may be electrically connected to the bump pad 103 through an interconnection circuit 105. The second bonding fingers BP2 may include a signal pad, a power pad, and a ground pad.

The third bonding fingers BP3 may be electrically connected to the third pad 130U of the third semiconductor chip 130 through the third bonding wire structure 135. The third bonding fingers BP3 may be electrically connected to the bump pad 103 through the interconnection circuit 105. The third bonding fingers BP3 may include a signal pad, a power pad, and a ground pad.

The first semiconductor chip 110 may include a first chip body 110S and a first pad 110U disposed on an upper portion of the first chip body 110S. The first semiconductor chip 110 may further include a first adhesive layer 110A disposed on a lower portion of the first chip body 110S.

The first semiconductor chip 110 may be mounted on a substrate 101 by the first adhesive layer 110A. The first adhesive layer 110A may include, for example, a die attach film (DAF). The first adhesive layer 110A may have a first thickness t1.

The first semiconductor chip 110 may be disposed adjacent to the second side 110S2 such that the first pad 110U may be adjacent to the first bonding finger BP1. The first pad 110U may be electrically connected to the first bonding fingers BP1 through the first bonding wire structure 115.

The second semiconductor chip 120 may include a second chip body 120S and a second pad 120U disposed on an upper portion of the second chip body 120S. The second semiconductor chip 120 may further include a second adhesive layer 120A disposed on a lower portion of the second chip body 120S.

The second semiconductor chip 120 may be offset in the first direction (e.g., X-direction) on the first semiconductor chip 110 such that the second pad 120U may be adjacent to the first side 110S1. Accordingly, the second semiconductor chip 120 may have a first overhang OH1. The first overhang OH1 may refer to a region in which the second semiconductor chip 120 protrudes further than a side surface of the first semiconductor chip 110 on the substrate 101.

The second semiconductor chip 120 may be attached to the first semiconductor chip 110 by a second adhesive layer 120A. The second adhesive layer 120A may include, for example, a die attach film (DAF). The second adhesive layer 120A may have a second thickness t2. In an example embodiment, the second thickness t2 may be greater than a first thickness t1.

The second adhesive layer 120A may cover the first bonding wire structure 115. For example, an upper portion 115U of the first bonding wire structure 115 may be covered by the second adhesive layer 120A. Here, the upper portion 115U may include a portion disposed at a level higher than a level of an upper surface of the first semiconductor chip 110 of the first bonding wire structure 115. In another aspect, a lower portion 115L of the first bonding wire structure 115 may not be covered by the second adhesive layer 120A. Here, the lower portion 115L may include a portion disposed at a level lower than a level of an upper surface of the first semiconductor chip 110 of the first bonding wire structure 115. For example, a lower portion 115L of the first bonding wire structure 115 may be molded by the encapsulant 180.

The third semiconductor chip 130 may include a third chip body 130S and a third pad 130U disposed on an upper portion of the third chip body 130S. The third semiconductor chip 130 may further include a third adhesive layer 130A disposed on a lower portion of the third chip body 130S.

The third semiconductor chip 130 may be offset in the first direction (e.g., X-direction) on the second semiconductor chip 120 such that the third pad 130U may be adjacent to the first side 110S1. Accordingly, the third semiconductor chip 130 may have a second overhang OH2. The second overhang OH2 may refer to a region in which the third semiconductor chip 130 protrudes further than a side surface of the second semiconductor chip 120 on the substrate 101. In an example embodiment, a length of the second overhang OH2 in the first direction (e.g., X-direction) may be greater than a length of the first overhang OH1.

The third semiconductor chip 130 may be attached to the second semiconductor chip 120 by a third adhesive layer 130A. The third adhesive layer 130A may include, for example, a die attach film (DAF). The third adhesive layer 130A may have a third thickness t3. In an example embodiment, the third thickness t3 may be greater than the first thickness t1.

The third adhesive layer 130A may cover the second bonding wire structure 125. For example, an upper portion 125U of the second bonding wire structure 125 may be covered by the third adhesive layer 130A. Here, the upper portion 125U may include a portion of the second bonding wire structure 125 disposed at a level higher than a level of an upper surface of the second semiconductor chip 120. In another aspect, a lower portion 125L of the second bonding wire structure 125 may not be covered by the third adhesive layer 130A. Here, the lower portion 125L may include a portion of the second bonding wire structure 125 disposed at a level lower than a level of an upper surface of the second semiconductor chip 120. For example, a lower portion 125L of the second bonding wire structure 125 may be molded by the encapsulant 180.

The first, second, and third semiconductor chips 110, 120, and 130 may include a nonvolatile memory semiconductor chip such as a flash memory, phase-change random access memory (PRAM), magnetoresistive random access memory (MRAM), ferroelectric random access memory (FeRAM), or resistive random access memory (RRAM), and/or a volatile memory semiconductor chip such as a dynamic random access memory (DRAM) or static random access memory (SRAM).

The plurality of bonding wire structures may include a first bonding wire structure 115 connecting the first pads 110U to the first finger pads BP1, a second bonding wire structure 125 connecting the second pads 120U to the second finger pads BP2, and a third bonding wire structure 135 connecting the third pads 130U to the third finger pads BP3.

The first bonding wire structure 115 may have an upper portion 115U covered by the second adhesive layer 120U and a lower portion 115L molded by an encapsulant 180. The upper and lower portions 115U and 115L may be defined with respect to an upper surface of the first semiconductor chip 110. For example, the upper portion 115U may include a portion disposed at a level higher than a level of an upper surface of the first semiconductor chip 110, and the lower portion 115L may include a portion disposed at a level lower than a level of an upper surface of the first semiconductor chip 110. An uppermost end of the upper portion 115U may be at a level lower than a level of an upper surface of the second adhesive layer 120U.

The second bonding wire structure 125 may have an upper portion 125U covered by the third adhesive layer 130U and a lower portion 125L molded by the encapsulant 180. The upper and lower portions 125U and 125L may be defined based on an upper surface of the second semiconductor chip 120. For example, the upper portion 125U may include a portion disposed at a level higher than a level of an upper surface of the second semiconductor chip 120, and the lower portion 125L may include a portion disposed at a level lower than a level of an upper surface of the second semiconductor chip 120. An uppermost end of the upper portion 125U may be at a level lower than a level of an upper surface of the third adhesive layer 130U.

The third bonding wire structure 135 may be molded by the encapsulant 180. An uppermost end of the third bonding wire structure 135 may be at a level lower than a level of an upper surface of the encapsulant 180.

The second bonding wire structure 125 may have a length greater than a length of the first bonding wire structure 115, and the third bonding wire structure 135 may have a length greater than a length of the second bonding wire structure 125.

The support structure 170 may be disposed between the third semiconductor chip 130 and the substrate 101 in a region in which the second overhang OH2 is formed. In another aspect, the support structure 170 may be formed between the second and third bonding fingers BP2 and BP3 in a region in which the second overhang OH2 is formed. In an example embodiment, the support structure 170 may be attached to the substrate 101 by an adhesive film 175 (e.g., DAF).

An upper surface of the support structure 170 may be substantially at the same level as an upper surface of the second semiconductor chip 120 with respect to the upper surface of the substrate 101. A width in the horizontal direction (e.g., X-direction)of the support structure 170 may be smaller than a thickness in the vertical direction (e.g., Z-direction).

A side surface of the support structure 170 and a side surface of the third semiconductor chip 130 may be aligned, but an example embodiment thereof is not limited thereto. For example, in terms of a cross-sectional area, the side surface of the third semiconductor chip 130 may protrude further than the side surface of the support structure 170.

A minimum distance d1 between the support structure 170 and the second bonding finger BP2 may be smaller than a minimum distance d2 between the support structure 170 and the third bonding finger BP3. Here, the minimum distance d1 may be defined as a minimum value of the distance between a lower surface of the support structure 170 and an upper surface of the second bonding finger BP2, and a minimum distance d2 may be defined as a minimum value of the distance between a lower surface of the support structure 170 and an upper surface of the third bonding finger BP3.

The support structure 170 may include an insulating material. The support structure 170 may include, for example, a dummy silicon spacer. In an example embodiment, the support structure 170 may be referred to as an insulating structure or a dummy spacer structure.

The encapsulant 180 may cover first to third semiconductor chips 110, 120, and 130, first to third bonding wire structures 115, 125, and 135, and a support structure 170 on the substrate 101. The encapsulant 180 may include, for example, a thermosetting resin such as an epoxy resin, a thermoplastic resin such as a polyimide, or a prepreg, ABF, FR-4, BT, epoxy molding compound (EMC), or the like.

According to an example embodiment, a length of the second overhang OH2 in the first direction (e.g., X-direction) may be greater than a length of the first overhang OH1 in the first direction. According to an example embodiment, by disposing the support structure 170 between the third semiconductor chip 130 and the substrate 101 in the region in which the second overhang OH2 is formed, a third bonding wire structure 135 having a reduced length may be formed. By the support structure 170, the third bonding wire structure 135 may be physically spaced apart from the first and second bonding wire structures 115 and 125, such that unnecessary shorts may be reduced or prevented. By the support structure 170, deflection of the third semiconductor chip 130 by the second overhang OH2 may be reduced or prevented.

In another aspect, the third semiconductor chip 130 may refer to an uppermost semiconductor chip disposed on a chip structure (e.g., CS) including three or more semiconductor chips (e.g., 110, 120 or the like). Accordingly, the support structure 170 may be understood as a structure disposed between the uppermost semiconductor chip and the substrate 101.

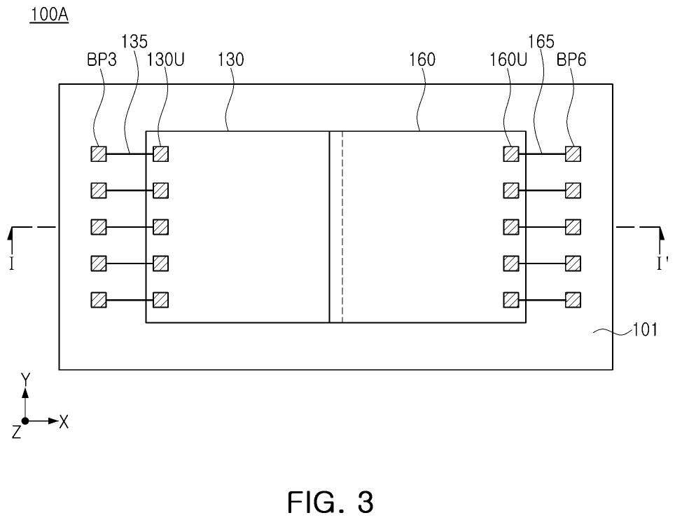

FIG. 3 is a plan diagram illustrating a semiconductor package according to an example embodiment.

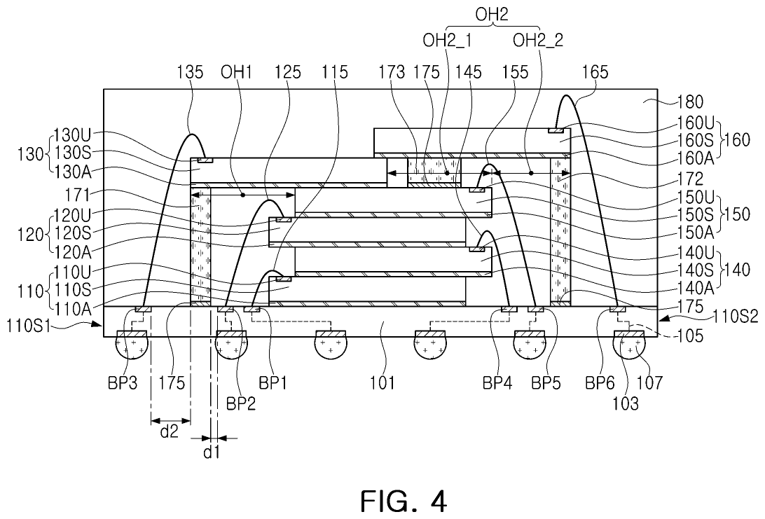

FIG. 4 is a cross-sectional diagram taken along line I-I′ in FIG. 3.

According to FIGS. 3 and 4, the semiconductor package 100A may be the same as or similar to the example described with reference to FIGS. 1 and 2, other than the configuration of including a plurality of semiconductor chips 110, 120, 130, 140, 150, and 160 stacked in a zigzag manner, and a plurality of support structures 171 and 172 adjacent to the first side and the second side 110S1 and 110S2, respectively. Hereinafter, only the differences of the semiconductor package 100A from the configuration of the semiconductor package 100 described with reference to FIGS. 1 and 2 may be selectively described.

A semiconductor package 100A in an example embodiment may include a substrate 101, a plurality of semiconductor chips (e.g., 110, 120, 130, 140, 150, and 160), and a plurality of bonding wire structures (e.g., 115, 125, and 135, 145, 155, and 165). Also, the semiconductor package 100 may further include a plurality of support structures 171, 172, and 173 and an adhesive film 175. Also, the semiconductor package 100 may further include an encapsulant 180.

The substrate 101 may have a first side 110S1 and a second side 110S2 opposing each other in the first direction (e.g., X-direction), and may include first to sixth bonding fingers BP1, BP2, BP3, BP4, BP5, and BP6 disposed on an upper surface.

The first bonding fingers BP1, the second bonding fingers BP2, and the third bonding fingers BP3 may be disposed in order in the first direction (e.g., X-direction) on the upper surface of the substrate 101 so as to be adjacent to the first side 110S1. For example, the first bonding fingers BP1, the second bonding fingers BP2, and the third bonding fingers BP3 may be arranged in order from the second side 110S2 to the first side 110S1 of the substrate 101.

The fourth bonding fingers BP4, the fifth bonding fingers BP5, and the sixth bonding fingers BP6 may be disposed in order in the first direction (e.g., X-direction) on the upper surface of the substrate 101 so as to be adjacent to the second side 110S2. For example, the fourth bonding fingers BP4, the fifth bonding fingers BP5, and the sixth bonding fingers BP6 may be arranged in order from the first side 110S1 to the second side 110S2 of the substrate 101.

The plurality of semiconductor chips may include, for example, first to sixth semiconductor chips 110, 120, 130, 140, 150, and 160 stacked in a zigzag manner on the substrate 101.

The first semiconductor chip 110 may include a first chip body 110S and a first pad 110U disposed on an upper portion of the first chip body 110S. The first semiconductor chip 110 may further include a first adhesive layer 110A disposed on a lower portion of the first chip body 110S. In an example embodiment, the first semiconductor chip 110 may be referred to as a 1-1 semiconductor chip, the first pad 110U may be referred to as a 1-1 pad, and the first adhesive layer 110A may be referred to as a 1-1 adhesive layer.

The first semiconductor chip 110 may be mounted on the substrate 101 by the first adhesive layer 110A.

The first semiconductor chip 110 may be disposed adjacent to the second side 110S2 such that the first pad 110U may be adjacent to the first bonding finger BP1. The first pad 110U may be electrically connected to the first bonding fingers BP1 through the first bonding wire structure 115. In an example embodiment, the first bonding wire structure 115 may be referred to as a 1-1 bonding wire structure, and the first bonding finger BP1 may be referred to as a 1-1 bonding finger.

The fourth semiconductor chip 140 may include a fourth chip body 140S and a fourth pad 140U disposed on an upper portion of the fourth chip body 140S. The fourth semiconductor chip 140 may further include a fourth adhesive layer 140A disposed on a lower portion of the fourth chip body 140S. In an example embodiment, the fourth semiconductor chip 140 may be referred to as a 2-1 semiconductor chip, the fourth pad 140U may be referred to as a 2-1 pad, and the fourth adhesive layer 140A may be referred to as a 2-1 adhesive layer.

The fourth semiconductor chip 140 may be disposed on the first semiconductor chip 110 such that the fourth pad 140U may be adjacent to the second side 110S2. The fourth semiconductor chip 140 may have an overhang. The fourth pad 140U may be electrically connected to the fourth bonding fingers BP4 through the fourth bonding wire structure 145. In an example embodiment, the fourth bonding wire structure 145 may be referred to as a 2-1 bonding wire structure, and the fourth bonding finger BP4 may be referred to as a 2-1 bonding finger.

The fourth semiconductor chip 140 may be attached to the first semiconductor chip 110 by the fourth adhesive layer 140A.

The second semiconductor chip 120 may include a second chip body 120S and a second pad 120U disposed on an upper portion of the second chip body 120S. The second semiconductor chip 120 may further include a second adhesive layer 120A disposed on a lower portion of the second chip body 120S. In an example embodiment, the second semiconductor chip 120 may be referred to as a 1-2 semiconductor chip, the second pad 120U may be referred to as a 1-2 pad, and the second adhesive layer 120A may be referred to as a 1-2 adhesive layer.

The second semiconductor chip 120 may be disposed on the third semiconductor chip 130 such that the second pad 120U may be adjacent to the first side 110S1. The second semiconductor chip 120 may have an overhang. The second pad 120U may be electrically connected to the second bonding fingers BP2 through the second bonding wire structure 125. In an example embodiment, the second bonding wire structure 125 may be referred to as a 1-2 bonding wire structure, and the second bonding finger BP2 may be referred to as a 1-2 bonding finger.

The second semiconductor chip 120 may be attached to the third semiconductor chip 130 by the second adhesive layer 120A.

A side surface of the second semiconductor chip 120 and a side surface of the first semiconductor chip 110 may be aligned, but an example embodiment thereof is not limited thereto. For example, in a planar view, the side surface of the second semiconductor chip 120 may protrude further than the side surface of the first semiconductor chip 110.

The fifth semiconductor chip 150 may include a fifth chip body 150S and a fifth pad 150U disposed on an upper portion of the fifth chip body 150S. The fifth semiconductor chip 150 may further include a fifth adhesive layer 150A disposed on a lower portion of the fifth chip body 150S. In an example embodiment, the fifth semiconductor chip 150 may be referred to as a 2-2 semiconductor chip, the fifth pad 150U may be referred to as a 2-2 pad, and the fifth adhesive layer 150A may be referred to as a 2-2 adhesive layer.

The fifth semiconductor chip 150 may be disposed on the second semiconductor chip 120 such that the fifth pad 150U may be adjacent to the second side 110S2. The fifth semiconductor chip 150 may have an overhang. The fifth pad 150U may be electrically connected to the fifth bonding fingers BP5 through the fifth bonding wire structure 155. In an example embodiment, the fifth bonding wire structure 155 may be referred to as a 2-2 bonding wire structure, and the fifth bonding finger BP5 may be referred to as a 2-2 bonding finger.

The fifth semiconductor chip 150 may be attached to the second semiconductor chip 120 by the fifth adhesive layer 150A.

A side surface of the third semiconductor chip 130 and a side surface of the fifth semiconductor chip 150 may be aligned, but an example embodiment thereof is not limited thereto. For example, in a planar view, the side surface of the fifth semiconductor chip 150 may protrude further than the side surface of the third semiconductor chip 130.

The third semiconductor chip 130 may include a third chip body 130S and a third pad 130U disposed on an upper portion of the third chip body 130S. The third semiconductor chip 130 may further include a third adhesive layer 130A disposed on a lower portion of the third chip body 130S. In an example embodiment, the third semiconductor chip 130 may be referred to as a 1-3 semiconductor chip, the third pad 130U may be referred to as a 1-3 pad, and the third adhesive layer 130A may be referred to as a 1-3 adhesive layer.

The third semiconductor chip 130 may be disposed on the fifth semiconductor chip 150 such that the third pad 130U may be adjacent to the first side 110S1. The third semiconductor chip 130 may have a first overhang OH1. The first overhang OH1 may refer to a region in which the third semiconductor chip 130 protrudes further than the side surface of the fifth semiconductor chip 150. The third pad 130U may be electrically connected to the third bonding fingers BP3 through the third bonding wire structure 135. In an example embodiment, the third bonding wire structure 135 may be referred to as a 1-3 bonding wire structure, and the third bonding finger BP3 may be referred to as a 1-3 bonding finger.

The third semiconductor chip 130 may be attached to the fifth semiconductor chip 150 by the third adhesive layer 130A.

In the region in which the first overhang OH1 is formed, the first support structure 171 may be disposed between the third semiconductor chip 130 and the substrate 101. In another aspect, the first support structure 171 may be formed between the second and third bonding fingers BP2 and BP3 in the region in which the first overhang OH1 is formed. In an example embodiment, the first support structure 171 may be attached to the substrate 101 by an adhesive film 175 (e.g., DAF).

An upper surface of the first support structure 171 may be substantially at the same level as an upper surface of the fifth semiconductor chip 150 with respect to the upper surface of the substrate 101. A width in the horizontal direction (e.g., X-direction) of the first support structure 171 may be smaller than a thickness in the vertical direction (e.g., Z-direction).

A side surface of the first support structure 171 and a side surface of the third semiconductor chip 130 may be aligned, but an example embodiment thereof is not limited thereto. For example, in terms of cross-sectional area, the side surface of the third semiconductor chip 130 may protrude further than the side surface of the first support structure 171.

A minimum distance d1 between the first support structure 171 and the second bonding finger BP2 may be smaller than a minimum distance d2 between the first support structure 171 and the third bonding finger BP3.

The sixth semiconductor chip 160 may include a sixth chip body 160S and a sixth pad 160U disposed on an upper portion of the sixth chip body 160S. The sixth semiconductor chip 160 may further include a sixth adhesive layer 160A disposed on a lower portion of the sixth chip body 160S. In an example embodiment, the sixth semiconductor chip 160 may be referred to as a 2-3 semiconductor chip, the sixth pad 160U may be referred to as a 2-3 pad, and the sixth adhesive layer 160A may be referred to as a 2-3 adhesive layer.

The sixth semiconductor chip 160 may be disposed on the third semiconductor chip 130 such that the sixth pad 160U may be adjacent to the second side 110S2. The sixth semiconductor chip 160 may have a second overhang OH2. The sixth pad 160U may be electrically connected to the sixth bonding fingers BP6 through the sixth bonding wire structure 165. In an example embodiment, the sixth bonding wire structure 165 may be referred to as a 2-3 bonding wire structure, and the sixth bonding finger BP6 may be referred to as a 2-3 bonding finger.

The sixth semiconductor chip 160 may be attached to the sixth semiconductor chip 160 by the sixth adhesive layer 160A.

The second overhang OH2 may refer to a region in which the sixth semiconductor chip 160 protrudes further than the side surface of the third semiconductor chip 130. The second overhang OH2 may include a 2-1 overhang OH_1 overlapping the fifth semiconductor chip 150 and a 2-2 overhang OH_2 not overlapping the fifth semiconductor chip 150. In another aspect, the 2-1 overhang OH_1 may be defined as a region in which the third support structure 173 is disposed, and the 2-2 overhang OH_2 may be defined as a region in which the second support structure 172 is disposed.

In the region in which the 2-2 overhang OH2_2 is formed, the second support structure 172 may be disposed between the sixth semiconductor chip 160 and the substrate 101. In another aspect, the second support structure 172 may be formed between the fifth and sixth bonding fingers BP5 and BP6 in the region in which the 2-2 overhang OH2_2 is formed. In an example embodiment, the second support structure 172 may be attached to the substrate 101 by an adhesive film 175 (e.g., DAF).

An upper surface of the second support structure 172 may be substantially at the same level as an upper surface of the third semiconductor chip 130 with respect to the upper surface of the substrate 101. A width in the horizontal direction (e.g., X-direction) of the second support structure 172 may be smaller than a thickness in the vertical direction (e.g., Z-direction).

A side surface of the second support structure 172 and a side surface of the sixth semiconductor chip 160 may be aligned, but an example embodiment thereof is not limited thereto. For example, in terms of a cross-sectional area, the side surface of the sixth semiconductor chip 160 may protrude further than the side surface of the second support structure 172.

A minimum distance between the second support structure 172 and the fifth bonding finger BP5 may be smaller than a minimum distance between the second support structure 172 and the third bonding finger BP3.

In the region in which the 2-1 overhang OH2_1 is formed, a third support structure 173 may be disposed between the fifth and sixth semiconductor chips 150 and 160. In an example embodiment, the third support structure 173 may be attached to the fifth semiconductor chip 150 by an adhesive film 175 (e.g., DAF).

An upper surface of the third support structure 173 may be substantially at the same level as an upper surface of the third semiconductor chip 130 with respect to the upper surface of the substrate 101. In an example embodiment, the third support structure 173 may be in contact with the third semiconductor chip 130.

The first, second, third, fourth, fifth, and sixth chip bodies 110S, 120S, 130S, 140S, 150S, and 160S may have the same size. For example, the first, second, third, fourth, fifth, and sixth chip bodies 110S, 120S, 130S, 140S, 150S, and 160S may have substantially the same length in the first direction (e.g., X-direction) and may have substantially the same width in the second direction (e.g., Y-direction).

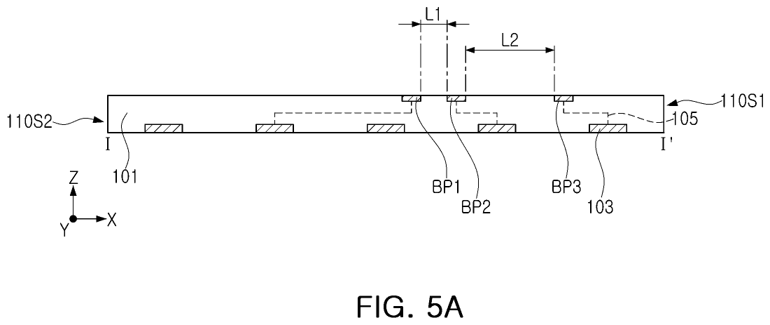

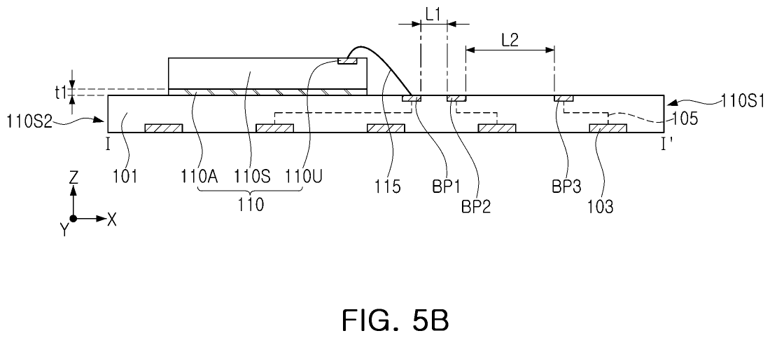

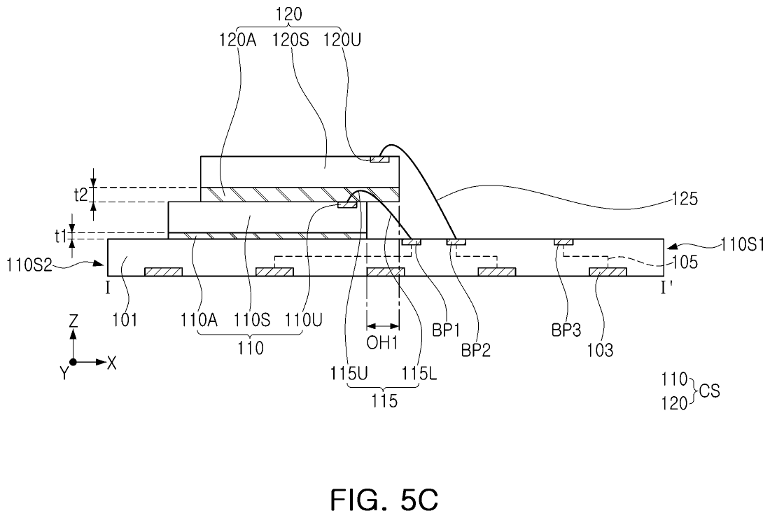

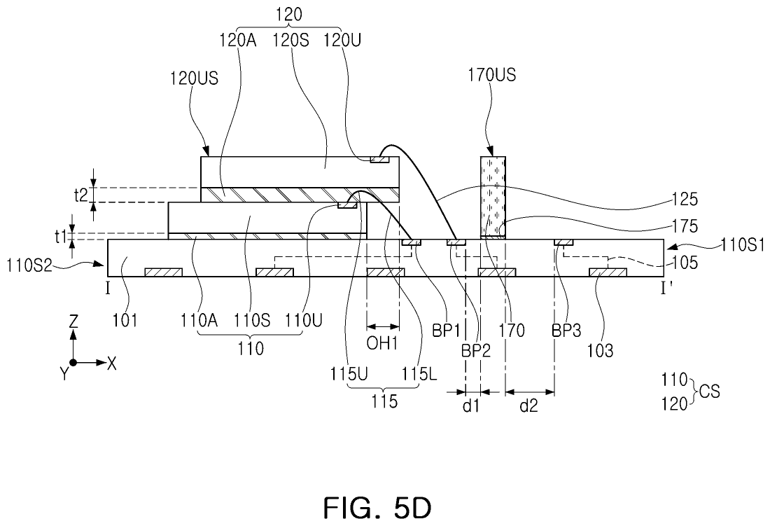

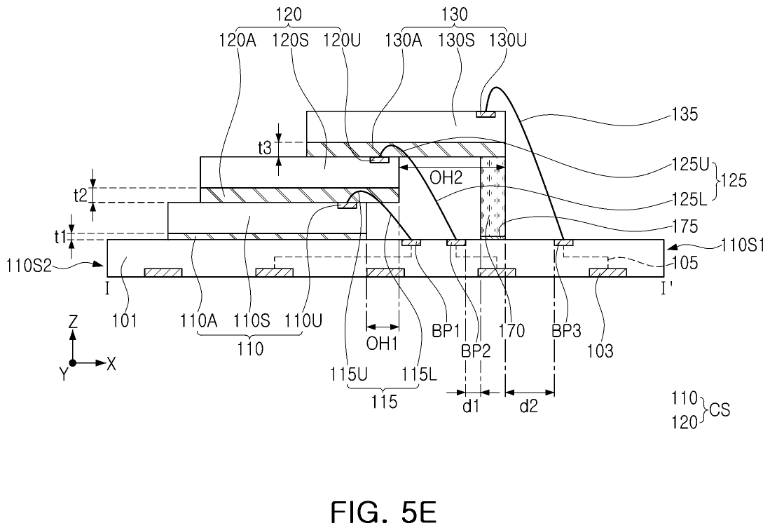

FIG. 5A, FIG. 5B, FIG. 5C, FIG. 5D and FIG. 5E are cross-sectional diagrams illustrating a process of manufacturing a semiconductor package according to an example embodiment.

Referring to FIG. 5A, a substrate 101 may be provided.

The substrate 101 having a first side 110S1 and a second side 110S2 opposing each other in the first direction (e.g., X-direction), and having an upper surface on which first, second and third bonding fingers BP1, BP2 and BP3 are disposed in order from the second side 110S2 towards the first side 110S1 may be provided. Each of the first, second and third bonding fingers BP1, BP2 and BP3 may be arranged on the upper surface of the substrate 101 in the second direction (e.g., Y-direction) (see FIG. 1).

A minimum distance L1 between the first and second bonding fingers BP1 and BP2 in the first direction (e.g., X-direction) may be smaller than a minimum distance L2 between the second and third bonding fingers BP2 and BP3 in the first direction (e.g., X-direction).

The substrate 101 may have a lower surface on which bump pads 103 are disposed. The substrate 101 may include an interconnection circuit 105 electrically connecting the first, second and third bonding fingers BP1, BP2 and BP3 to the bump pads 103.

Referring to FIG. 5B, a first semiconductor chip 110 may be formed on the substrate 101.

The first semiconductor chip 110 including a first chip body 110S, a first pad 110U disposed on an upper portion of the first chip body 110S, and a first adhesive layer 110A disposed on a lower portion of the first chip body 110S may be formed on the substrate 101.

The first semiconductor chip 110 may be attached to the substrate 101 by the first adhesive layer 110A. The first semiconductor chip 110 may be disposed such that the first pad 110U may be adjacent to the first bonding finger BP1.

Thereafter, a first bonding wire structure 115 electrically connecting the first pad 110U to the first bonding finger BP1 may be formed.

Referring to FIG. 5C, a second semiconductor chip 120 may be formed on the first semiconductor chip 110.

A second semiconductor chip 120 including a second chip body 120S, a second pad 120U disposed on an upper portion of the second chip body 120S, and a second adhesive layer 120A disposed on a lower portion of the second chip body 120S may be formed on the first semiconductor chip 110.

The second semiconductor chip 120 may be offset in the first direction (e.g., X-direction) on the first semiconductor chip 110 such that the second pad 120U may be adjacent to the first side 110S1. Accordingly, the second semiconductor chip 120 may have a first overhang OH1.

The second adhesive layer 120A may cover the first bonding wire structure 115. For example, an upper portion 115U of the first bonding wire structure 115 may be covered by the second adhesive layer 120A. Here, the upper portion 115U may include a portion of the first bonding wire structure 115 disposed at a level higher than a level of an upper surface of the first semiconductor chip 110. In another aspect, a lower portion 115L of the first bonding wire structure 115 may not be covered by the second adhesive layer 120A. Here, the lower portion 115L may include a portion of the first bonding wire structure 115 disposed at a level lower than a level of an upper surface of the first semiconductor chip 110.

Thereafter, a second bonding wire structure 125 electrically connecting the second pad 120U to the second bonding finger BP2 may be formed.

Referring to FIG. 5D, a support structure 170 may be formed on the substrate 101.

A support structure 170 may be formed between the second and third bonding fingers BP2 and BP3. An upper surface 170US of the support structure 170 and an upper surface 120US of the second semiconductor chip 120 may be substantially at the same level with respect to an upper surface of the substrate 101.

Referring to FIG. 5E, a third semiconductor chip 130 may be formed on the second semiconductor chip 120 and the support structure 170.

A third semiconductor chip 130 including a third chip body 130S, a third pad 130U disposed on an upper portion of the third chip body 130S, and a third adhesive layer 130A disposed on a lower portion of the third chip body 130S may be formed on the second semiconductor chip 120 and the support structure 170.

The third semiconductor chip 130 may be offset in the first direction (e.g., X-direction) on the second semiconductor chip 120 such that the third pad 130U may be adjacent to the first side 110S1. Accordingly, the third semiconductor chip 130 may have a second overhang OH2. A length in the first direction (e.g., X-direction) of the second overhang OH2 may be greater than a length in the first direction of the first overhang OH1.

The third adhesive layer 130A may cover the second bonding wire structure 125. For example, an upper portion 125U of the second bonding wire structure 125 may be covered by the third adhesive layer 130A. Here, the upper portion 125U may include a portion of the second bonding wire structure 125 disposed at a level higher than a level of an upper surface of the second semiconductor chip 120. In another aspect, a lower portion 125L of the second bonding wire structure 125 may not be covered by the third adhesive layer 130A. Here, the lower portion 125L may include a portion of the second bonding wire structure 125 disposed at a level lower than a level of an upper surface of the second semiconductor chip 120.

Thereafter, a third bonding wire structure 135 electrically connecting the third pad 130U to the third bonding finger BP3 may be formed.

Thereafter, an encapsulant 180 covering first to third semiconductor chips 110, 120, and 130, first to third bonding wire structures 115, 125, and 135 and a support structure 170 may be formed on the substrate 101 (see FIG. 2). Thereafter, connection bumps 107 may be formed on the bump pads 103.

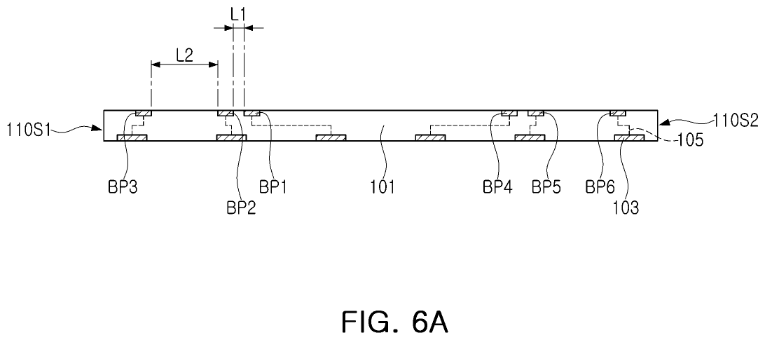

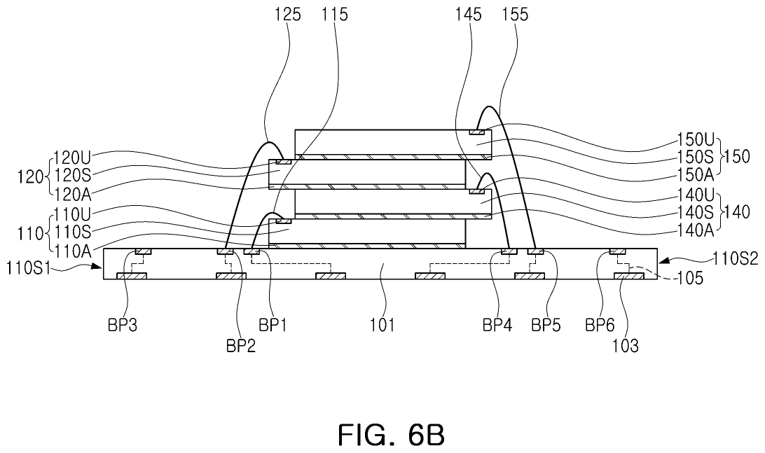

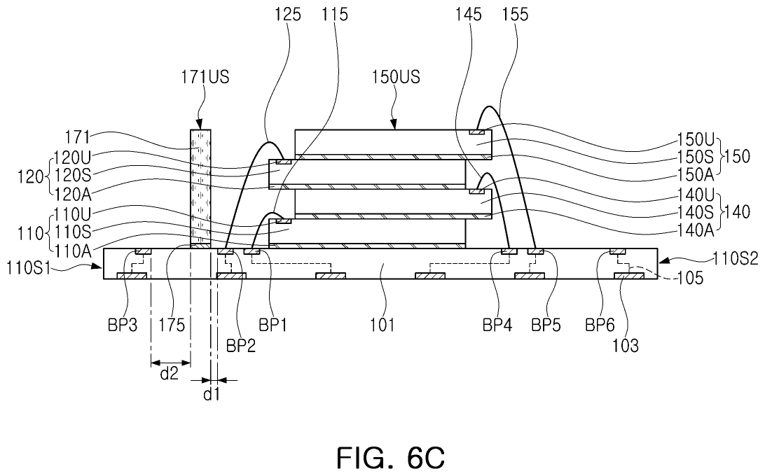

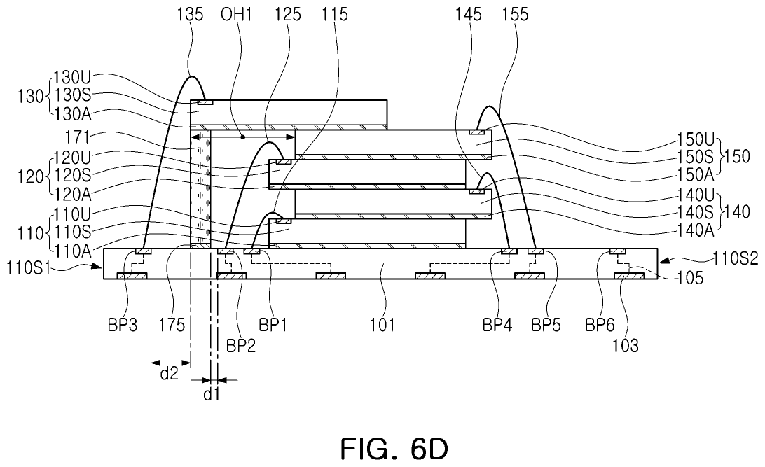

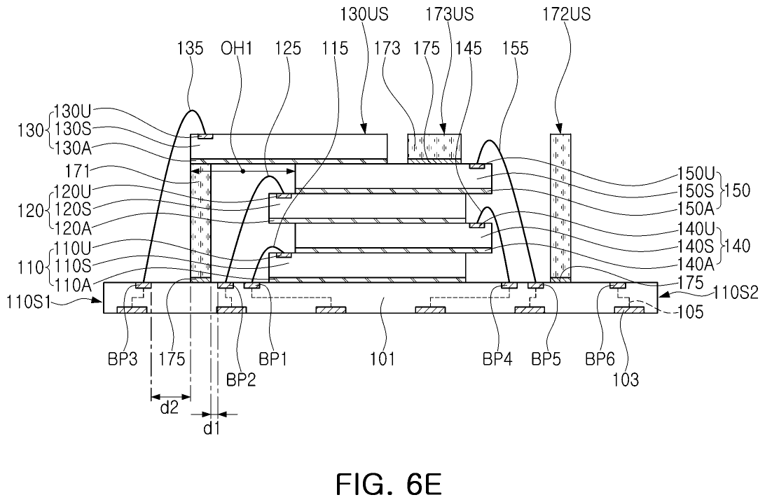

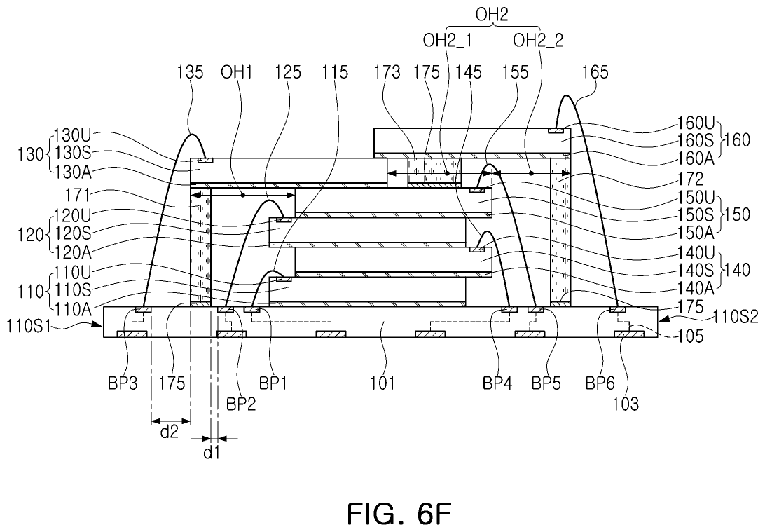

FIG. 6A, FIG. 6B, FIG. 6C, FIG. 6D, FIG. 6E and FIG. 6F are cross-sectional diagrams illustrating a process of manufacturing a semiconductor package according to an example embodiment.

Referring to FIG. 6A, a substrate 101 may be provided.

The substrate 101 having a first side 110S1 and a second side 110S2 opposing each other in the first direction (e.g., X-direction), and having an upper surface on which first, second and third bonding fingers BP1, BP2, and BP3 arranged in order from the second side 110S2 toward the first side 110S1 and fourth, fifth and sixth bonding fingers BP4, BP5, and BP6 disposed in sequence from the first side 110S1 toward the second side 110S2 are disposed may be provided.

A minimum distance L1 in the first direction (e.g., X-direction) between the first and second bonding fingers BP1 and BP2 may be smaller than a minimum distance L2 in the first direction (e.g., X-direction) between the second and third bonding fingers BP2 and BP3. Also, a minimum distance in the first direction (e.g., X-direction) between the fourth and fifth bonding fingers (BP4, BP5) may be smaller than a minimum distance in the first direction (e.g., X-direction) between the fifth and sixth bonding fingers BP2, BP3.

The substrate 101 may have a lower surface on which bump pads 103 are disposed. The substrate 101 may include an interconnection circuit 105 electrically connecting the first, second and third bonding fingers BP1, BP2 and BP3 to the bump pads 103.

Referring to FIG. 6B, a plurality of semiconductor chips 110, 120, 140, and 150 may be formed on the substrate 101 in a zigzag manner.

A 1-1 semiconductor chip 110 may be formed on the substrate 101.

A 1-1 semiconductor chip 110 may be attached to the substrate 101 by a 1-1 adhesive layer 110A. The 1-1 semiconductor chip 110 may be disposed such that the 1-1 pad 110U may be adjacent to the 1-1 bonding finger BP1.

Thereafter, a 1-1 bonding wire structure 115 electrically connecting the 1-1 pad 110U to the 1-1 bonding finger BP1 may be formed.

A 2-1 semiconductor chip 140 may be formed on the 1-1 semiconductor chip 110.

The 2-1 semiconductor chip 140 may be attached to the 1-1 semiconductor chip 110 by the 2-1 adhesive layer 140A. The 2-1 semiconductor chip 140 may be disposed such that a 2-1 pad 140U may be adjacent to a 2-1 bonding finger BP4.

Thereafter, a 2-1 bonding wire structure 145 electrically connecting the 2-1 pad 140U to the 2-1 bonding finger BP4 may be formed.

The 1-2 semiconductor chip 120 may be formed on the 2-1 semiconductor chip 140.

The 1-2 semiconductor chip 120 may be attached on the 2-1 semiconductor chip 140 by the 1-2 adhesive layer 120A. The 1-2 semiconductor chip 120 may be disposed such that the 1-2 pad 120U may be adjacent to the 1-2 bonding finger BP2.

Thereafter, a 1-2 bonding wire structure 125 electrically connecting the 1-2 pad 120U to the 1-2 bonding finger BP2 may be formed.

A 2-2 semiconductor chip 150 may be formed on the 1-2 semiconductor chip 120.

The 2-2 semiconductor chip 150 may be attached to the 1-2 semiconductor chip 120 by the 2-2 adhesive layer 150A. The 2-2 semiconductor chip 150 may be disposed such that the 2-2 pad 150U may be adjacent to the 2-2 bonding finger BP5.

Thereafter, a 2-2 bonding wire structure 155 electrically connecting the 2-2 pad 150U to the 2-2 bonding finger BP5 may be formed.

Referring to FIG. 6C, a first support structure 171 adjacent to the first side 110S1 of the substrate 101 may be formed.

A first support structure 171 may be formed between the 1-2 and 1-3 bonding fingers BP2 and BP3. An upper surface 171US of the first support structure 171 and an upper surface 150US of the 2-2 semiconductor chip 150 may be substantially at the same level with respect to an upper surface of the substrate 101.

Referring to FIG. 6D, a 1-3 semiconductor chip 130 may be formed on the 2-2 semiconductor chip 150 and the first support structure 171.

The 1-3 semiconductor chip 130 may be formed on the 2-2 semiconductor chip 150 and the first support structure 171.

The 1-3 semiconductor chip 130 may be offset in the first direction (e.g., X-direction) on the 2-2 semiconductor chip 150 such that the 1-3 pad 130U may be adjacent to the first side 110S1. Accordingly, the 1-3 semiconductor chip 130 may have a first overhang OH1.

Thereafter, a 1-3 bonding wire structure 135 electrically connecting the 1-3 pad 130U to the 1-3 bonding finger BP3 may be formed.

Referring to FIG. 6E, a second support structure 172 adjacent to the second side 110S2 of the substrate 101 and a 2-2 Third support structure 173 disposed on the semiconductor chip 150 may be formed.

A second support structure 172 may be formed between the 2-2 and 2-3 bonding fingers BP5 and BP6. An upper surface 172US of the second support structure 172 and an upper surface 130US of the 1-3 semiconductor chip 130 may be substantially at the same level with respect to an upper surface of the substrate 101.

A third support structure 173 may be formed on the 2-2 semiconductor chip 150. An upper surface 173US of the third support structure 173 and an upper surface 130US of the 1-3 semiconductor chip 130 may be substantially at the same level with respect to an upper surface of the substrate 101.

Referring to FIG. 6F, a 2-3 semiconductor chip 160 may be formed on the 1-3 semiconductor chip 130 and the second and third support structures 172 and 173.

A 2-3 semiconductor chip 160 may be formed on the 1-3 semiconductor chip 130 and the second and third support structures 172 and 173.

The 2-3 semiconductor chip 160 may be offset in the first direction (e.g., X-direction) formed on the 1-3 semiconductor chip 130 such that the 2-3 pad 160U may be adjacent to the second side 110S2. Accordingly, the 2-3 semiconductor chip 160 may have a second overhang OH2.

The second overhang OH2 may be defined as including the 2-1 overhang OH_1 overlapping the 2-2 semiconductor chip 150 and the 2-2 overhang OH_2 not overlapping the 2-2 semiconductor chip 150.

Thereafter, the 2-3 bonding wire structure 165 electrically connecting the 2-3 pad 160U to the 2-3 bonding finger BP6 may be formed.

Thereafter, an encapsulant 180 covering the plurality of semiconductor chips 110, 120, 130, 140, 150, and 160, the plurality of bonding wire structures 115, 125, and 135, 145, 155, and 165 and the plurality of support structures 171, 172, and 1 may be formed on the substrate 101 (see FIG. 4). Thereafter, connection bumps 107 may be formed on the bump pads 103.

According to the aforementioned example embodiments, a semiconductor package having improved reliability and a method of manufacturing the same may be provided.

According to an example embodiment of the present disclosure, a method of manufacturing a semiconductor package includes providing a substrate having an upper surface on which first, second, and third bonding fingers are disposed; forming a first semiconductor chip on the substrate, wherein the first semiconductor chip includes a first pad disposed on an upper portion and a first adhesive layer disposed on a lower portion; forming a first bonding wire structure electrically connecting the first pad of the first semiconductor chip to the first bonding finger; forming a second semiconductor chip on the first semiconductor chip, wherein the second semiconductor chip includes a second pad disposed on an upper portion and a second adhesive layer disposed on a lower portion, and the second adhesive layer covers an upper portion of the first bonding wire structure; forming a second bonding wire structure electrically connecting the second pad of the second semiconductor chip to the second bonding finger; forming a support structure on the substrate, wherein the support structure is formed between the second and third bonding fingers; forming a third semiconductor chip on the second semiconductor chip and the support structure, wherein the third semiconductor chip includes a third pad disposed on an upper portion and a third adhesive layer disposed on a lower portion, and the third adhesive layer covers the second bonding wire structure on an upper portion; and forming a third bonding wire structure electrically connecting the third pad of the third semiconductor chip to the third bonding finger.

Also, the second semiconductor chip may have a first overhang in the first direction, the third semiconductor chip may have a second overhang in the first direction, and a length of the second overhang is greater than a length of the first overhang.

Also, a distance between the first and second bonding fingers may be smaller than a distance between the second and third bonding fingers.

Also, a minimum distance between the second bonding finger and the support structure is smaller than a minimum distance between the third bonding finger and the support structure.

Also, a thickness of each of the second and third adhesive layers is greater than a thickness of the first adhesive layer.

Also, a width in a horizontal direction of the support structure may be smaller than a height in a vertical direction of the support structure.

Also, the first, second and third semiconductor chips may include semiconductor substrates having the same size.

Also, the method may further include forming an encapsulant covering the first, second, and third semiconductor chips, the first, second, and third bonding wire structures, and the support structure on the substrate.

Also, the encapsulant may cover a lower portion of each of the first and second bonding wire structures.

Also, the substrate may further include bump pads, and an interconnection circuit electrically connecting the bump pads to the first, second, and third bonding fingers, and the method may further include forming bump structures on a lower portion of the bump pads of the substrate.

While the example embodiments have been illustrated and described above, it will be configured as apparent to those skilled in the art that modifications and variations could be made without departing from the scope of the present disclosure as defined by the appended claims.

What is claimed is:

1. A semiconductor package, comprising:
a substrate having an upper surface on which a first bonding finger, a second bonding finger, and a third bonding finger are disposed;
a first semiconductor chip disposed on the substrate, and including a first pad disposed on an upper portion of the first semiconductor chip and a first adhesive layer disposed on a lower portion of the first semiconductor chip;
a first bonding wire structure electrically connecting the first pad of the first semiconductor chip to the first bonding finger;
a second semiconductor chip disposed on the first semiconductor chip, and including a second pad disposed on an upper portion of the second semiconductor chip and a second adhesive layer disposed on a lower portion of the second semiconductor chip, the second adhesive layer covering an upper portion of the first bonding wire structure, and the second semiconductor chip having a first overhang in a first direction;
a second bonding wire structure electrically connecting the second pad of the second semiconductor chip to the second bonding finger;
a third semiconductor chip disposed on the second semiconductor chip, and including a third pad disposed on an upper portion of the third semiconductor chip, and a third adhesive layer disposed on a lower portion of the third semiconductor chip, the third adhesive layer covering an upper portion of the second bonding wire structure, and the third semiconductor chip having a second overhang in the first direction;
a third bonding wire structure electrically connecting the third pad of the third semiconductor chip to the third bonding finger; and
a support structure disposed between the second bonding finger and the third bonding finger and formed between the third semiconductor chip and the substrate.

2. The semiconductor package of claim 1, wherein an upper surface of the support structure is substantially at the same level as an upper surface of the second semiconductor chip with respect to the upper surface of the substrate.

3. The semiconductor package of claim 1, wherein a side surface of the support structure and a side surface of the third semiconductor chip are aligned.

4. The semiconductor package of claim 1, wherein a minimum distance between the first bonding finger and the second bonding finger is less than a minimum distance between the second bonding finger and the third bonding finger.

5. The semiconductor package of claim 1, further comprising:
an adhesive film between the support structure and the substrate.

6. The semiconductor package of claim 1, wherein a width in a horizontal direction of the support structure is smaller than a height in a vertical direction of the support structure.

7. The semiconductor package of claim 1, wherein a length of the second overhang is greater than a length of the first overhang.

8. The semiconductor package of claim 1, wherein a thickness of each of the second and third adhesive layers is greater than a thickness of the first adhesive layer.

9. The semiconductor package of claim 1,
wherein the substrate further includes bump pads, and an interconnection circuit electrically connecting the bump pads to the first, second, and third bonding fingers, and
wherein the semiconductor package further includes connection bumps disposed on a lower portion of the bump pads of the substrate.

10. The semiconductor package of claim 1, further comprising:
an encapsulant covering the first, second, and third semiconductor chips, the first, second, and third bonding wire structures, and the support structure on the substrate.

11. The semiconductor package of claim 10, wherein the encapsulant covers a lower portion of each of the first and second bonding wire structures.

12. The semiconductor package of claim 1, wherein each of the first, second and third semiconductor chips includes a chip body having the same size.

13. A semiconductor package, comprising:
a substrate having a first side and a second side opposing each other in a first direction, and an upper surface on which 1-1, 1-2, and 1-3 bonding fingers arranged in order toward the first side are disposed;
a 1-1 semiconductor chip disposed on the substrate and including a 1-1 pad disposed on an upper portion of the 1-1 semiconductor chip;
a 1-1 bonding wire structure electrically connecting the 1-1 pad of the 1-1 semiconductor chip to the 1-1 bonding finger and extending toward the first side;
a 1-2 semiconductor chip disposed on the 1-1 semiconductor chip and including a 1 -2pad disposed on an upper portion of the 1-2 semiconductor chip;
a 1-2 bonding wire structure electrically connecting the 1-2 pad of the 1-2 semiconductor chip to the 1-2 bonding finger and extending toward the first side;
a 1-3 semiconductor chip disposed on the 1-2 semiconductor chip and including a 1 -3pad disposed on an upper portion of the 1-3 semiconductor chip, the 1-3 semiconductor chip having a first overhang region;
a 1-3 bonding wire structure electrically connecting the 1-3 pad of the 1-3 semiconductor chip to the 1-3 bonding finger and extending toward the first side; and
a first support structure disposed between the 1-3 semiconductor chip and the substrate in the first overhang region,
wherein the first support structure is disposed between the 1-2 and 1-3 bonding fingers, and
wherein a minimum distance between the first support structure and the 1-2 bonding finger is smaller than a minimum distance between the first support structure and the 1-3 bonding finger.

14. The semiconductor package of claim 13, wherein an upper surface of the first support structure is substantially at the same level as an upper surface of the 1-2 semiconductor chip.

15. The semiconductor package of claim 13,
wherein the substrate further includes 2-1, 2-2, and 2-3 bonding fingers disposed on the upper surface of the substrate and arranged in order toward the second side, and
wherein the semiconductor package further includes:
a 2-1 semiconductor chip disposed between the 1-1 and 1-2 semiconductor chips and including a 2-1 pad disposed on an upper portion of the 2-1 semiconductor chip;
a 2-1 bonding wire structure electrically connecting the 2-1 pad of the 2-1 semiconductor chip to the 2-1 bonding finger and extending toward the second side;
a 2-2 semiconductor chip disposed between the 1-2 and 1-3 semiconductor chips and including a 2-2 pad disposed on an upper portion of the 2-2 semiconductor chip;
a 2-2 bonding wire structure electrically connecting the 2-2 pad of the 2-2 semiconductor chip to the 2-2 bonding finger and extending toward the second side;
a 2-3 semiconductor chip disposed on the 1-3 semiconductor chip and including a 2 -3pad disposed on an upper portion of the 2-3 semiconductor chip, the 2-3 semiconductor chip having a second overhang region, and the second overhang region including a 2-1 overhang region formed on the 2-2 semiconductor chip and a 2-2 overhang region formed on the substrate;
a 2-3 bonding wire structure electrically connecting the 2-3 pad of the 2-3 semiconductor chip to the 2-3 bonding finger and extending toward the second side; and
a second support structure disposed between the 2-3 semiconductor chip and the substrate in the 2-2 overhang region.

16. The semiconductor package of claim 15,
wherein an upper surface of the first support structure is substantially at the same level as an upper surface of the 2-2 semiconductor chip, and
wherein an upper surface of the second support structure is substantially at the same level as an upper surface of the 1-3 semiconductor chip.

17. The semiconductor package of claim 15, further comprising:
an insulating structure in the 2-1 overhang region.

18. The semiconductor package of claim 17,
wherein a height in a vertical direction of the first support structure is greater than a width in a horizontal direction of the first support structure,
wherein a height in the vertical direction of the second support structure is greater than a width in the horizontal direction of the second support structure, and
wherein a height in the vertical direction of the insulating structure is less than a width in the horizontal direction of the insulating structure.

19. A semiconductor package, comprising:
a substrate having an upper surface on which a plurality of bonding fingers and a connection finger are disposed;
a chip structure disposed on the substrate and including a plurality of semiconductor chips including pads disposed on upper surfaces thereof, respectively, wherein the plurality of semiconductor chips are offset and stacked in a first direction;
a bonding wire structure electrically connecting the pads of the plurality of semiconductor chips to a bonding finger closest to the pad among the plurality of bonding fingers;
a semiconductor die disposed on the chip structure and including a connection pad disposed on an upper portion of the semiconductor die, wherein the semiconductor die has an overhang in the first direction;
an insulating structure disposed between the plurality of bonding fingers and the connection finger, and formed between the semiconductor die and the substrate; and
a connection wire structure electrically connecting the connection pad of the semiconductor die to the connection finger.

20. The semiconductor package of claim 19, wherein a minimum distance between a bonding finger closest to the insulating structure among the plurality of bonding fingers and the insulating structure is smaller than a minimum distance between the connection finger and the insulating structure.
